(19) United States
(12) Patent Application Publication
(10) Pub. No.: US 2023/0056639 A1
(43) Pub. Date: Feb. 23, 2023

(54) ORGANIC ELECTROLUMINESCENT DEVICE, DISPLAY PANEL, AND DISPLAY DEVICE

(71) Applicant: BOE Technology Group Co., Ltd., Beijing (CN)

(72) Inventors: Yong WU, Beijing (CN); Xiaojin ZHANG, Beijing (CN)

(21) Appl. No.: 17/789,693

(22) PCT Filed: Aug. 4, 2021
(86) PCT No.: PCT/CN2021/110675

§ 371 Date: Jun. 28, 2022

(30) Foreign Application Priority Data
Sep. 25, 2020 (CN) 202011021774.4

(51) Int. Cl. H01L 51/50

(52) U.S. Cl. CPC H01L 51/5064; H01L 51/5096; H01L 51/5092; H01L 51/508; H01L 51/5088

(57) ABSTRACT

The present invention provides an organic electroluminescent device, a display panel, and a display device. An organic electroluminescent device, including: an anode and a cathode, arranged in opposite; a light-emitting layer, between the anode and the cathode; a first auxiliary function layer, between the light-emitting layer and the anode; and a second auxiliary function layer, between the light-emitting layer and the cathode; where the light-emitting layer comprises a first compound, a second compound and a third compound; a Stokes shift between an absorption spectrum of the second compound and an emission spectrum of the second compound is smaller than 70 nm; and a doping mass ratio of the second compound in the light-emitting layer is smaller than 50 wt %.

### CROSS REFERENCE TO RELATED APPLICATIONS

The present disclosure claims priority to the Chinese Patent Application No. 202011021774.4, filed to the China National Intellectual Property Administration on Sep. 25, 2020 and entitled “ORGANIC ELECTROLUMINESCENT DEVICE, DISPLAY PANEL, AND DISPLAY DEVICE”, the entire contents of which are incorporated herein by reference.

### FIELD

The present disclosure relates to the technical field of display, in particular to an organic electroluminescent device, a display panel, and a display apparatus.

### BACKGROUND

In recent years, an organic light-emitting display (OLED), as a new type of flat panel display, has attracted more and more attention. Because of features including active lighting, high brightness, high resolution, wide viewing angle, fast response, color saturation, lightness and thinness, low energy consumption, flexibility and the like, it is known as a dream display, and has become a hot mainstream display product in the market.

### SUMMARY

In an aspect, an embodiment of the present disclosure provides an organic electroluminescent device, including: an anode and a cathode arranged in opposite, a light-emitting layer between the anode and the cathode, a first auxiliary function layer between the light-emitting layer and the anode, and a second auxiliary function layer between the light-emitting layer and the cathode; where,

the light-emitting layer includes a first compound, a second compound and a third compound, a Stokes shift between an absorption spectrum of the second compound and an emission spectrum of the second compound is smaller than 70 nm, and a doping mass ratio of the second compound in the light-emitting layer is smaller than 50 wt %.

In some embodiments, an overlap ratio between the emission spectrum of the second compound and an emission spectrum of the first compound is greater than 30%.

In some embodiments, an overlap ratio between the emission spectrum of the second compound and an emission spectrum of the third compound is greater than 20%.

In some embodiments, a position of a peak value of an emission spectrum of the first compound ranges from 400 nm to 550 nm;

a peak value of the emission spectrum of the second compound is greater than the peak value of the emission spectrum of the first compound;

a position difference between the peak value of the emission spectrum of the second compound and the peak value of the emission spectrum of the first compound ranges from 30 nm to 100 nm;

a peak value of an emission spectrum of the third compound is greater than the peak value of the emission spectrum of the second compound;

a position difference between the peak value of the emission spectrum of the third compound and the peak value of the emission spectrum of the second compound ranges from 30 nm to 100 nm;

a position of a peak value of the absorption spectrum of the second compound ranges from 200 nm to 500 nm; and

a position of a peak value of an absorption spectrum of the third compound ranges from 430 nm to 600 nm.

In some embodiments, a triplet-state energy level of the second compound is greater than a triplet-state energy level of the third compound.

In some embodiments, a triplet-state energy level of the first compound is greater than the triplet-state energy level of the third compound.

In some embodiments, the triplet-state energy level of the first compound is smaller than a triplet-state energy level of a film layer in the first auxiliary function layer in contact with the light-emitting layer; and the triplet-state energy level of the first compound is smaller than a triplet-state energy level of a film layer in the second auxiliary function layer in contact with the light-emitting layer.

In some embodiments, the first auxiliary function layer includes at least one of following: a hole injection layer, a hole transport layer or an electron blocking layer; and the second auxiliary function layer includes at least one of following: an electron injection layer, an electron transport layer or a hole blocking layer.

In some embodiments, the second compound has a characteristic of emitting delayed fluorescence.

In another aspect, an embodiment of the present disclosure further provides a display panel, including the plurality of above organic electroluminescent devices.

In another aspect, an embodiment of the present disclosure further provides a display apparatus, including the above display panel.

### BRIEF DESCRIPTION OF THE DRAWINGS

FIG. 1 is a schematic structural diagram of an organic electroluminescent device provided by an embodiment of the present disclosure.

FIG. 2 is an absorption-emission spectrum diagram of an organic electroluminescent device provided by an embodiment of the present disclosure.

FIG. 3 is a diagram of a current density-voltage relationship of all embodiments in experimental data provided by an embodiment of the present disclosure.

FIG. 4 is a diagram of a current efficiency-current density relationship of all embodiments in experimental data provided by an embodiment of the present disclosure.

### DETAILED DESCRIPTION OF THE EMBODIMENTS

In order to make objectives, technical solutions and advantages of the embodiments of the present disclosure clearer, the technical solutions of embodiments of the present disclosure will be clearly and completely described below with reference to the accompanying drawings of the embodiments of the present disclosure. It should be noted that the sizes and shapes of various patterns in the accompanying drawings do not reflect the true ratio, and are only intended to illustrate the content of the present disclosure schematically. In addition, the same or similar numerals refer to the same or similar elements or elements having the same or similar functions throughout. Obviously, the described embodiments are some, but not all, embodiments of the present disclosure. Based on the embodiments in the present disclosure, all other embodiments acquired by those of ordinary skill in the art without creative work shall fall within the protection scope of the present disclosure.

Unless otherwise defined, technical or scientific terms used herein should have the ordinary meaning as understood by those of ordinary skill in the art to which the present disclosure belongs. The terms “first”, “second” and the like used in the description and claims of the present disclosure do not indicate any order, quantity or importance, but are only used to distinguish different components. “Comprise” or “include” and similar words mean that the elements or objects appearing before the word encompass the elements or objects recited after the word and their equivalents, but do not exclude other elements or objects. “Inside”, “outside”, “up”, “down” and the like are only used to indicate the relative positional relationship, and when the absolute position of the described object changes, the relative positional relationship may also change accordingly.

In OLED products, a light-emitting layer is a core of a whole device, the light-emitting layer impacts the whole performance of the device most obviously, therefore, selection of a material system also has various strict rules, for example, matching between an Lowest Unoccupied Molecular Orbital, LUMO, energy level and an Highest Occupied Molecular Orbital, HOMO, energy level of a host material and a guest material and energy level matching between adjacent layers may severely impact the transport efficiency of electrons and holes. A carrier mobility of the host material also has a large impact on an exciton complex region, the luminous efficiency of the guest material directly impacts the luminous efficiency of the device, the higher the overlapping of an emission spectrum of the host material and an absorption spectrum of the guest material is, the more favorable the exciton energy is to transfer to achieve efficient light emitting. Matching of a singlet-state energy level and a triplet-state energy level of the host material and a singlet-state energy level and a triplet-state energy level of the guest material also has a great impact on exciton energy transfer of the light-emitting layer. Therefore, after strict selection, the available matching system of the host material and the guest material is greatly reduced, which limits approaches to improve an organic light-emitting device.

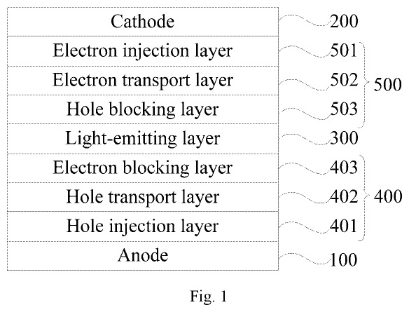

An organic electroluminescent device provided by an embodiment of the present disclosure, as shown in FIG. 1, the organic electroluminescent device includes: an anode 100 and a cathode 200 arranged in opposite, a light-emitting layer 300 between the anode 100 and the cathode 200, a first auxiliary function layer 400 between the light-emitting layer 300 and the anode 100, and a second auxiliary function layer 500 between the light-emitting layer 300 and the cathode 200.

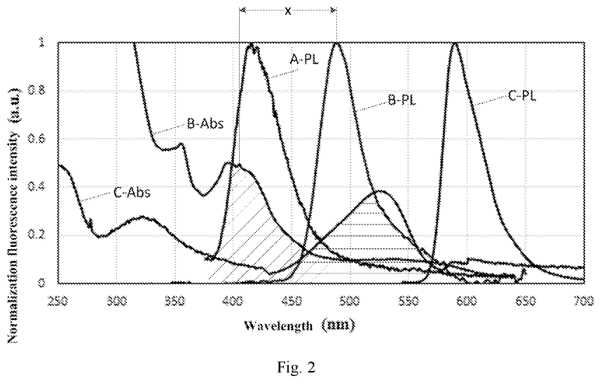

The light-emitting layer 300 includes a first compound A, a second compound B and a third compound C, as shown in FIG. 2, a Stokes shift x between an absorption spectrum Abs of the second compound B and an emission spectrum PL of the second compound B is smaller than 70 nm, and a doping mass ratio of the second compound B in the light-emitting layer 300 is smaller than 50 wt %.

In some embodiments, it may be considered that the first compound A is a host material, the third compound C is a guest material, and the second compound B is a matching material. The embodiment of the present disclosure provides a new selection principle of a material matching system of the light-emitting layer 300 by adjusting a material system of the light-emitting layer 300. A matching material having a narrow Strokes shift is doped between the host material and the guest material, so that a spectral overlapping degree of the host material, the matching material and the guest material is greatly improved, exciton energy efficient transfer between the host material and the guest material is achieved, the luminous efficiency of the organic electroluminescent device can be improved, the organic electroluminescent device with various excellent properties is achieved, and a selection range of a material system of the light-emitting layer 300 is also greatly widened.

In some embodiments, as shown in FIG. 2, an overlap ratio (a region where oblique lines are distributed in FIG. 2) between an absorption spectrum Abs of the second compound B and an emission spectrum PL of the first compound A is generally greater than 30%.

In some embodiments, the larger the overlap ratio (the higher the overlap ratio is) between the absorption spectrum Abs of the second compound B and the emission spectrum PL of the first compound A is, the more favorable the exciton energy is to transfer from the first compound A to the second compound B to achieve the efficient energy transport.

In some embodiments, as shown in FIG. 2, an overlap ratio (a region where transverse lines are distributed in FIG. 2) between the emission spectrum PL of the second compound B and an absorption spectrum Abs of the third compound C is generally greater than 20%. Further, an overlapping area between the emission spectrum PL of the second compound B and the absorption spectrum Abs of the third compound C is preferably greater than 40%.

In some embodiments, the larger the overlap ratio (the higher the overlap ratio is) between the emission spectrum PL of the second compound B and the absorption spectrum Abs of the third compound C is, the more favorable the exciton energy is to transfer from the second compound B to the third compound C to achieve the efficient energy transport.

In some embodiments, a position of a peak value range of the emission spectrum of the first compound ranges from 400 nm to 550 nm, a peak value of the emission spectrum of the second compound is greater than the peak value of the emission spectrum of the first compound, a position difference between the peak value of the emission spectrum of the second compound and the peak value of the emission spectrum of the first compound ranges from 30 nm to 100 nm, a peak value of an emission spectrum of the third compound is greater than a peak value of the emission spectrum of the second compound, and a position difference between the peak value of the emission spectrum of the third compound and the peak value of the emission spectrum of the second compound ranges from 30 nm to 100 nm; and a position of a peak value range of the absorption spectrum of the second compound ranges from 200 nm to 500 nm, and a position of a peak value range of the absorption spectrum of the third compound ranges from 430 nm to 600 nm. Thus, there is a larger overlapping area between the absorption spectrum Abs of the second compound B and the emission spectrum PL of the first compound A, and there is a larger overlapping area between the emission spectrum PL of the second compound B and the absorption spectrum Abs of the third compound C.

In some embodiments, the Strokes shift x between the absorption spectrum Abs and the emission spectrum PL of the second compound B is preferably smaller than 50 nm.

In some embodiments, the smaller the Strokes shift x between the absorption spectrum Abs and the emission spectrum PL of the second compound B is, the better, which is favorable to fix the light-emitting layer 300 within a wavelength range of the same color, for example, the light-emitting layer 300 is fixed within a blue light-emitting wavelength range.

In some embodiments, a triplet-state energy level T1 (B) of the second compound B generally needs to be higher than a triplet-state energy level T1 (C) of the third compound C, which is favorable to transfer excitons from the second compound B with a high energy level to the third compound C with a low energy level, and effectively prevent energy from passing back to the second compound B from the third compound C.

In some embodiments, a triplet-state energy level T1 (A) of the first compound A is higher than the triplet-state energy level T1 (C) of the third compound C, which is favorable to transfer excitons from the first compound A with a high energy level to the third compound C with a low energy level, and effectively prevent energy from passing back to the first compound A from the third compound C.

In some embodiments, the triplet-state energy level T1 (A) of the first compound A is generally higher than a triplet-state energy level T1 (B) of the second compound B, which is favorable to transfer excitons from the first compound A with a high energy level to the second compound B with a low energy level, and effectively prevent energy from passing back to the first compound A from the second compound B.

In some embodiments, the second compound B may selects a material having a characteristic of emitting delayed fluorescence, the material may enable triplet-state excitons to form singlet-state excitons through reverse intersystem crossing, so as to ensure that exciton energy may be transferred to the third compound through Forrest energy transfer, Dexter energy transfer is inhibited to avoid energy loss, and the device efficiency is improved.

In some embodiments, a doping mass ratio of the second compound B in the light-emitting layer 300 is generally smaller than 50 wt %, that is, a proportion of the second compound B in the light-emitting layer 300 is smaller than a proportion of the first compound A in the light-emitting layer 300.

In some embodiments, the third compound C may selects a fluorescence-emission material, or a phosphorescence emission material, which is not limited herein. In addition, a doping mass ratio of the third compound C in the light-emitting layer 300 is generally smaller than 5 wt %, for example, doping proportions such as 0.1 wt %, 1 wt % and 2 wt % may be selected.

In some embodiments, as shown in FIG. 1, the first auxiliary function layer 400 may include at least one of the following: a hole injection layer 401, a hole transport layer 402 or an electron blocking layer 403; and the second auxiliary function layer 500 may include at least one of the following: an electron injection layer 501, an electron transport layer 502 or a hole blocking layer 503.

In some embodiments, FIG. 1 takes the first auxiliary function layer 400 including the hole injection layer 401, the hole transport layer 402 and the electron blocking layer 403 and the second auxiliary function layer 500 including the electron injection layer 501, the electron transport layer 502 and the hole blocking layer 503 as an example for illustration, and an overlapping relationship between specific film layers refers to FIG. 1. In practical application, the auxiliary function layer may be selected according to the needs, for example, the first auxiliary function layer 400 only selects the electron blocking layer 403, the second auxiliary function layer 500 only selects the hole blocking layer 503, and the detailed description is not made herein.

In some embodiments, when the above organic electroluminescent device provided by the embodiment of the present disclosure is practically manufactured, the anode 100, the hole injection layer 401, the hole transport layer 402, the electron blocking layer 403, the light-emitting layer 300, the hole blocking layer 503, the electron transport layer 502, the electron injection layer 501 and the cathode 200 are sequentially formed on a base substrate.

In some embodiments, the base substrate may be selected from any transparent substrate material, such as glass and polyimide.

The anode 100 is selected from a high-work function electrode material, such as transparent oxides of ITO and IZO, and also may be a combined electrode formed by Ag/ITO, Ag/IZO, CNT/ITO, CNT/IZO, GO/ITO and GO/IZO.

The hole injection layer 401 may be selected from injection materials such as MoO3, F4-TCNQ and HAT-CN, and also may be formed by performing P type doping in a hole transport material through coevaporation. A thickness of the hole injection layer 401 is selected as 5 nm-30 nm.

The hole transport layer 402 has a good hole transport characteristic, and may be selected from materials such as NPB, m-MTDATA, TPD and TAPC, and a thickness of the hole transport layer 402 is selected as 10 nm-2000 nm.

A hole mobility of the electron blocking layer 403 is higher 1-2 orders of magnitude than an electronic mobility, transport of electrons can be effectively blocked, the electron blocking layer 403 may be selected from materials such as TCTA, and a thickness of the electron blocking layer 403 is selected as 5 nm-100 nm.

The host material in the light-emitting layer 300, namely the first compound A, may be selected from materials such as mCBP, CBP, mCP, TCTA, DMQA and TPA, and a thickness of the light-emitting layer 300 is selected as 20 nm-100 nm.

An electronic mobility of the hole blocking layer 503 is higher 1-2 orders of magnitude than a hole mobility, transport of holes can be effectively blocked, the hole blocking layer 503 may be selected from materials such as CBP, Bphen and TPBI, and a thickness of the hole blocking layer 503 is selected as 5 nm-100 nm.

The electron transport layer 502 has a good electron transport characteristic, and may be selected from materials such as TmPyPB and B4PyPPM, and a thickness of the electron transport layer 502 is selected as 20 nm-100 nm.

The electron injection layer 501 may be selected from materials such as LiF, Yb and LiQ, and a thickness of the electron injection layer 501 is selected as 1 nm-10 nm.

The cathode 200 may be selected from materials such as Mg and Ag.

In some embodiments, the triplet-state energy level T1 (A) of the first compound A is generally smaller than a triplet-state energy level of a film layer in the first auxiliary function layer 400 in contact with the light-emitting layer, for example, in the structure as shown in FIG. 1, the triplet-state energy level T1 (A) of the first compound A is smaller than a triplet-state energy level T1 (403) of the electron blocking layer 403; and at the same time, the triplet-state energy level T1 (A) of the first compound A is generally smaller than a triplet-state energy level of a film layer in the second auxiliary function layer 500 in contact with the light-emitting layer, for example, in the structure as shown in FIG. 1, the triplet-state energy level T1 (A) of the first compound A is smaller than a triplet-state energy level T1 (503) of the hole blocking layer 503.

In some embodiments, the triplet-state energy level T1 (A) of the first compound A is smaller than a triplet-state energy level of the adjacent film layer, the energy can be effectively prevented from being transferred to the adjacent film layer from the light-emitting layer 300, the excitons can be effectively limited in the light-emitting layer 300, and the luminous efficiency is improved.

In some embodiments, the structure of the above organic electroluminescent device provided by the embodiment of the present disclosure is adopted to manufacture one comparative example and four embodiments, wherein, materials and thicknesses of the hole injection hole, the hole transport layer, the electron blocking layer, the hole blocking layer, the electron transport layer and the electron injection layer in the comparative example and the embodiments are the same, in the light-emitting layer, the first compound adopts TCTA, the second compound adopts DABNA, the third compound adopts PhtBuPAD, and a specific structural formula is as follows.

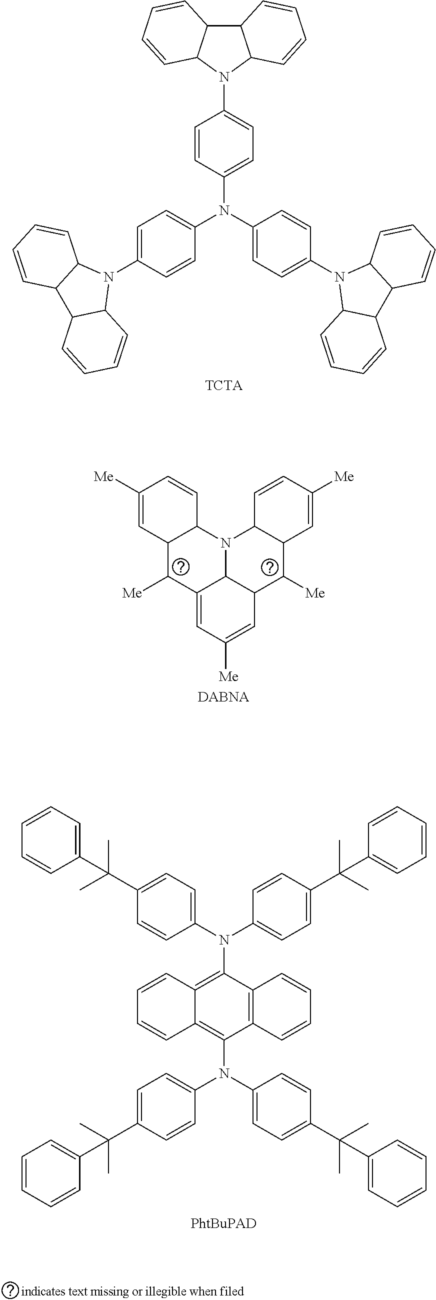 [SMILES: C1=CC2C3C=CC=CC3N(c3ccc(N(c4ccc(N5C6C=CC=CC6C6C=CC=CC65)cc4)c4ccc(N5C6C=CC=CC6C6C=CC=CC65)cc4)cc3)C2C=C1 ; CC1=CC2C(C)C3=CC(C)=CC4C(C)C5C=C(C)C=CC5N(C2C=C1)C34 ; "DABNA" ; "PhtBuPAD" ; CC(C)(c1ccccc1)c1ccc(N(c2ccc(C(C)(C)c3ccccc3)cc2)c2c3ccccc3c(N(c3ccc(C(C)(C)c4ccccc4)cc3)c3ccc(C(C)(C)c4ccccc4)cc3)c3ccccc23)cc1]

Doping proportions of the third compound in the comparative example and all the embodiments are each 1 wt %, and a difference is that doping proportions of the second compound in the light-emitting layer are different. Detailed parameters are shown in Table 1.

TABLE 1

| | Comparative | | Embodiment | | Embodiment | | Embodiment | | Embodiment | |
|---|---|---|---|---|---|---|---|---|---|---|
| | example | | 1 | | 2 | | 3 | | 4 | |
| Hole | 5 | nm | 5 | nm | 5 | nm | 5 | nm | 5 | nm |
| injection | | | | | | | | | | |
| layer | | | | | | | | | | |
| Hole | 40 | nm | 40 | nm | 40 | nm | 40 | nm | 40 | nm |
| transport | | | | | | | | | | |
| layer | | | | | | | | | | |
| Electron | 5 | nm | 5 | nm | 5 | nm | 5 | nm | 5 | nm |
| blokcing | | | | | | | | | | |
| layer | | | | | | | | | | |
| Proportion | 0 | | 0.5 | wt % | 0.3 | wt % | 0.8 | wt % | 1 | wt % |
| of second | | | | | | | | | | |
| compound | | | | | | | | | | |
| Hole | 10 | nm | 10 | nm | 10 | nm | 10 | nm | 10 | nm |
| blocking | | | | | | | | | | |
| layer | | | | | | | | | | |
| Electron | 40 | nm | 40 | nm | 40 | nm | 40 | nm | 40 | nm |
| transport | | | | | | | | | | |
| layer | | | | | | | | | | |
| Electron | 1 | nm | 1 | nm | 1 | nm | 1 | nm | 1 | nm |
| injection | | | | | | | | | | |
| layer | | | | | | | | | | |
| Cathode | 100 | nm | 100 | nm | 100 | nm | 100 | nm | 100 | nm |

Device properties of the above comparative example and embodiments 1-4 are compared from the following data: turn-on voltage Von, current efficiency CE, power efficiency PE, external quantum efficiency EQE, luminous chromaticity CIE, and data obtained through specific measurement are shown in Table 2.

TABLE 2

| | Comparative | Embodiment | Embodiment | Embodiment | Embodiment |
|---|---|---|---|---|---|
| | example | 1 | 2 | 3 | 4 |
| Von (V) | 2.3 | 2.3 | 2.3 | 2.3 | 2.3 |
| CE (cd/A) | 20.06 | 17.4 | 18.8 | 20.7 | 21.5 |
| PE (lm/W) | 24.4 | 20.8 | 22.1 | 24.8 | 25.8 |
| EQE | 26.4 | 22.6 | 24.2 | 26.9 | 27.9 |
| CIE | 0.51, 0.37 | 0.51, 0.37 | 0.51, 0.37 | 0.49, 0.42 | 0.48, 0.44 |

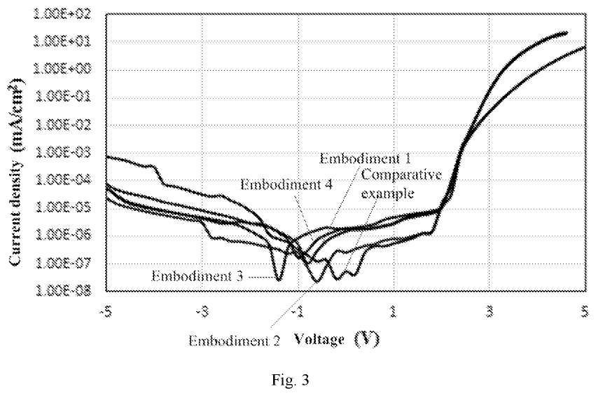

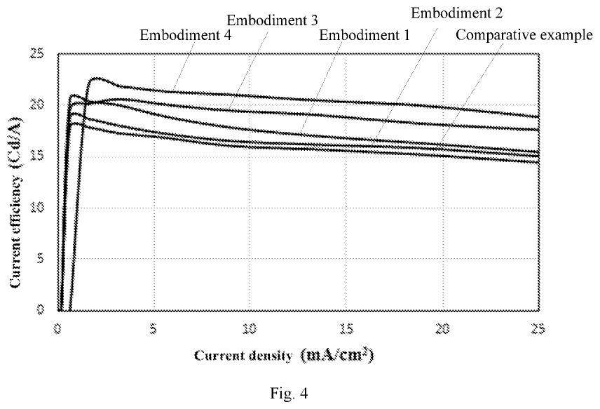

It can be seen from Table 2 and FIG. 3-FIG. 4, according to embodiments 1-4 provided by the present disclosure, the second compound with different concentrations is added in the light-emitting layer relative to the comparative example, the device efficiency can be improved under the condition of ensuring constant power consumption, in addition, it can be seen from embodiments 1-4, with increasing of the proportion of the second compound within a certain range, and the efficiency is also increased accordingly.

Based on the same inventive concept, an embodiment of the present disclosure further provide a display panel, including the plurality of above organic electroluminescent devices provided by the embodiment of the present disclosure. Since a principle of the display panel solving the problem is similar to that of the above organic electroluminescent device, implementation of the display panel may refer to implementation of the organic electroluminescent device, and repetition will not be made.

Based on the same inventive concept, an embodiment of the present disclosure further provide a display apparatus, including the above display panel provided by the embodiment of the present disclosure. The display apparatus may be: a mobile phone, a tablet computer, a television, a monitor, a notebook computer, a digital photo frame, a navigator and any product or component with a display function. Other essential components of the display apparatus should be understood by those skilled in the art, and will not be repeated herein, nor should it be used as a limitation of the present disclosure. The implementation of the display apparatus may refer to the implementation of the above organic electroluminescent device, and the repetition will not be made.

According to the above organic electroluminescent device, display panel and display apparatus provided by the present disclosure, by adjusting the material system of the light-emitting layer, the new selection principle of the material matching system of the light-emitting layer is provided, the matching material having the Stokes shift is doped between the host material and the guest material, so that the spectral overlapping degree of the host material, the matching material and the guest material is greatly improved, exciton energy efficient transfer between the host material and the guest material is achieved, the luminous efficiency of the organic electroluminescent device can be improved, the organic electroluminescent devices with various excellent properties are achieved, and the selection range of the light-emitting layer material system is also greatly widened.

Obviously, those skilled in the art can make various modifications and variations to the embodiments of the present disclosure without departing from the spirit and scope of the embodiments of the present disclosure. As such, provided that these modifications and variations of the embodiments of the present disclosure fall within the scope of the claims of the present disclosure and their equivalents, the present disclosure is also intended to cover such modifications and variations.

1. An organic electroluminescent device, comprising:
an anode and a cathode, arranged in opposite;
a light-emitting layer, between the anode and the cathode;
a first auxiliary function layer, between the light-emitting layer and the anode; and
a second auxiliary function layer, between the light-emitting layer and the cathode; wherein,
the light-emitting layer comprises a first compound, a second compound and a third compound;
a Stokes shift between an absorption spectrum of the second compound and an emission spectrum of the second compound is smaller than 70 nm; and
a doping mass ratio of the second compound in the light-emitting layer is smaller than 50 wt %.

2. The organic electroluminescent device according to claim 1, wherein an overlap ratio between the absorption spectrum of the second compound and an emission spectrum of the first compound is greater than 30%.

3. The organic electroluminescent device according to claim 1, wherein an overlap ratio between the emission spectrum of the second compound and an absorption spectrum of the third compound is greater than 20%.

4. The organic electroluminescent device according to claim 1, wherein a position of a peak value of an emission spectrum of the first compound ranges from 400 nm to 550 nm;
a peak value of the emission spectrum of the second compound is greater than the peak value of the emission spectrum of the first compound;
a position difference between the peak value of the emission spectrum of the second compound and the peak value of the emission spectrum of the first compound ranges from 30 nm to 100 nm;
a peak value of an emission spectrum of the third compound is greater than the peak value of the emission spectrum of the second compound;
a position difference between the peak value of the emission spectrum of the third compound and the peak value of the emission spectrum of the second compound ranges from 30 nm to 100 nm;
a position of a peak value of the absorption spectrum of the second compound ranges from 200 nm to 500 nm; and
a position of a peak value of an absorption spectrum of the third compound ranges from 430 nm to 600 nm.

5. The organic electroluminescent device according to claim 1, wherein a triplet-state energy level of the second compound is higher than a triplet-state energy level of the third compound.

6. The organic electroluminescent device according to claim 1, wherein a triplet-state energy level of the first compound is higher than a triplet-state energy level of the third compound.

7. The organic electroluminescent device according to claim 1, wherein a triplet-state energy level of the first compound is smaller than a triplet-state energy level of a film layer in the first auxiliary function layer in contact with the light-emitting layer; and
the triplet-state energy level of the first compound is smaller than a triplet-state energy level of a film layer in the second auxiliary function layer in contact with the light-emitting layer.

8. The organic electroluminescent device according to claim 7, wherein the first auxiliary function layer comprises at least one of following: a hole injection layer, a hole transport layer or an electron blocking layer; and
the second auxiliary function layer comprises at least one of following: an electron injection layer, an electron transport layer or a hole blocking layer.

9. The organic electroluminescent device according to claim 1, wherein the second compound has a characteristic of emitting delayed fluorescence.

10. A display panel, comprising a plurality of the organic electroluminescent devices according to claim 1.

11. A display apparatus, comprising the display panel according to claim 10.

12. The display panel according to claim 10, wherein an overlap ratio between the absorption spectrum of the second compound and an emission spectrum of the first compound is greater than 30%.

13. The display panel according to claim 10, wherein an overlap ratio between the emission spectrum of the second compound and an absorption spectrum of the third compound is greater than 20%.

14. The display panel according to claim 10, wherein a position of a peak value of an emission spectrum of the first compound ranges from 400 nm to 550 nm;
a peak value of the emission spectrum of the second compound is greater than the peak value of the emission spectrum of the first compound;
a position difference between the peak value of the emission spectrum of the second compound and the peak value of the emission spectrum of the first compound ranges from 30 nm to 100 nm;
a peak value of an emission spectrum of the third compound is greater than the peak value of the emission spectrum of the second compound;
a position difference between the peak value of the emission spectrum of the third compound and the peak value of the emission spectrum of the second compound ranges from 30 nm to 100 nm;
a position of a peak value of the absorption spectrum of the second compound ranges from 200 nm to 500 nm; and
a position of a peak value of an absorption spectrum of the third compound ranges from 430 nm to 600 nm.

15. The display panel according to claim 10, wherein a triplet-state energy level of the second compound is higher than a triplet-state energy level of the third compound.

16. The display panel according to claim 10, wherein a triplet-state energy level of the first compound is higher than a triplet-state energy level of the third compound.

17. The display panel according to claim 10, wherein a triplet-state energy level of the first compound is smaller than a triplet-state energy level of a film layer in the first auxiliary function layer in contact with the light-emitting layer; and
the triplet-state energy level of the first compound is smaller than a triplet-state energy level of a film layer in the second auxiliary function layer in contact with the light-emitting layer.

18. The display panel according to claim 17, wherein the first auxiliary function layer comprises at least one of following: a hole injection layer, a hole transport layer or an electron blocking layer; and
the second auxiliary function layer comprises at least one of following: an electron injection layer, an electron transport layer or a hole blocking layer.

19. The display panel according to claim 10, wherein the second compound has a characteristic of emitting delayed fluorescence.
